(19) United States
(12) Patent Application Publication
(10) Pub. No.: US 2014/0190737 A1
(43) Pub. Date: Jul. 10, 2014

(54) Remote Controller Casing

(71) Applicant: ADVANCE SECURITY INC, New Taipei City (TW)

(72) Inventor: YEONG SUEI CHEN, New Taipei City (TW)

(73) Assignee: ADVANCE SECURITY INC, New Taipei City (TW)

(21) Appl. No.: 13/736,942

(22) Filed: Jan. 8, 2013

(51) Int. Cl. H05K 5/02

(52) U.S. Cl. CPC H05K 5/02
USPC 174/535

(57) ABSTRACT

A remote controller casing includes a front shell; a rear shell, which has an assembly means with the front shell, wherein the assembly means is coupled and fixed for the rear shell and the frond shell to develop an accommodating space to hold a printed circuit board, and the rear shell further comprises a battery bay whose one interior edge is designed to have a convex part, at least one concave part at one side, and a groove corresponding to the concave part and located at an opposite side; and a back cover, which includes at least one clasper at one ide which is opposite to the concave part, and at least one clamping part at an opposite side.

### BACKGROUND OF THE INVENTION

1. Field of the Invention

The present invention relates to a remote controller casing, particularly to a remote controller casing which prevents a battery held inside from drop or collision related to an external force, facilitating replacement of a battery, and featuring colorful casings and convenient assembly.

2. Description of the Prior Art

The variety of hand-held remote controllers available in the market such as electric-door remote controller, automotive remote controller, TV remote controller or mobile phone with a remote controller's functions have facilitated our lives and taken as a symbol of progressive technology. However, those owners of compact hand-held technical products with smaller size or volume may confront some incidents such as a remote controller unavoidably dropped or collided, battery falling down, or damage attributed to weak structure. Based on the above descriptions, some drawbacks still exist in these modern remote controllers: badly assembled structure causing drop of inner components, a remote controller difficultly opened or annoyingly assembled/disassembled. Accordingly, these troubles should be overcome for users who expect to freely manipulate remote controllers or the general public who want to conveniently assemble/disassemble these compact products.

Considering drawbacks or inconvenience of remote controllers based on the prior art, the applicant who holding spirit of innovation and constant improvement has created a remote controller casing by his insight and professional knowledge.

### SUMMARY OF THE INVENTION

The present invention is intended for providing a remote controller casing which features simple structure and scientific rationality and is easily assembled/disassembled.

To reach the above purposes, the present invention adopts technical measures as follows.

A remote controller casing comprises: a front shell; a rear shell, which has an assembly means with said front shell, wherein said assembly means is coupled and fixed for said rear shell and said frond shell to develop an accommodating space to hold a printed circuit board, and said rear shell further comprises a battery bay whose one interior edge is designed to have a convex part, at least one concave part at one side, and a groove corresponding to said concave part and located at an opposite side; and a back cover, which comprises at least one clasper at one ide which is opposite to said concave part, and at least one clamping part at an opposite side; wherein, when said front shell is assembled with said rear shell, said battery bay matches a space developed by a conductive spring and a conducting strip which are located at two sides of said printed circuit board respectively, so that a battery is held between said conductive spring and said conducting strip by means of said battery bay and is not separated from said conductive spring and said conducting strip due to said convex part; wherein, said clasper on said back cover snaps and resists said concave part first, and said rear shell is consequently covered through said clamping part, and then said back cover and said rear shell are combined with said clamping part snapping said groove under press.

In the present invention, said assembly means refers to at least one assembling section which is associated with a relative position between said front shell and said rear shell.

In the present invention, said assembling section comprises components used in assembly such as fastener, screw and threaded hole or a combination of said components.

In the present invention, the remote controller further comprises a monitor module which is electrically connected to said printed circuit board for displaying information related to said printed circuit board.

In the present invention, said printed circuit board further comprises a plurality of push buttons which are able to control settings related to said printed circuit board.

In the present invention, said rear shell further comprises a ring-like part which is used to link or hang said remote controller.

It can be seen from above disclosures that the present invention has advantages as follows.
(a) Easy assembly: The present invention of a remote controller casing can be easily assembled in an uncomplicated method with several steps for engagement; a back cover (or a front shell) is directly replaced by an alternative one (with a different color).
(b) Stability against drop: A battery held inside is not separated from a battery bay on which there is a convex part designed when a remote controller falls down or is collided.
(c) Personalized design: Based on personal preference, a front shell, a rear shell or a back cover which is easily assembled or disassembled can be replaced by an alternative one with a different style.

### BRIEF DESCRIPTION OF THE DRAWINGS

FIG. 1 is an exploded view of the present invention of a remote controller casing;

FIG. 2 is a schematic view of the present invention of a remote controller casing with a front shell and a rear shell assembled;

FIG. 3 is a side view of the present invention of a remote controller casing with a rear shell assembled onto a back cover;

FIG. 4 is a front oblique view of the present invention of a remote controller casing which has been assembled;

FIG. 5 is a rear oblique view of the present invention of a remote controller casing which has been assembled.

### DETAILED DESCRIPTION OF THE PREFERRED EMBODIMENT

The present invention will be further interpreted in embodiments and accompanying drawings for clear disclosures of its purpose, technical measures, and advantages. It should be notable that embodiments herein are intended for explaining rather than restricting the present invention.

The present invention is further explained in embodiments and accompanying drawings as follows:

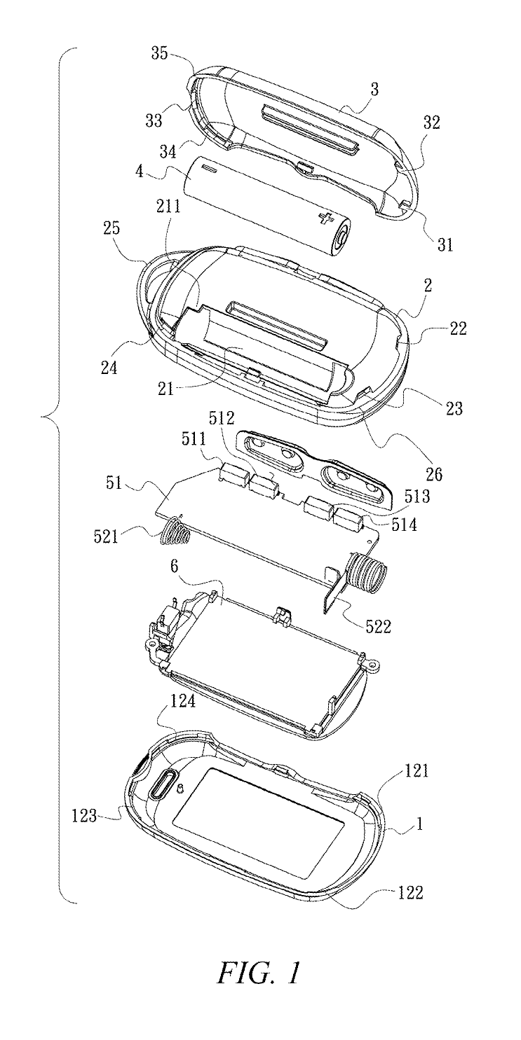

Refer to FIG. 1 which is an exploded view of the present invention of a remote controller casing. As shown in FIG. 1, the present invention of a remote controller casing comprises a front shell 1, a rear shell 2 and a back cover 3. The front shell 1 and a monitor module 6 constitute a front cover of the remote controller casing. The front shell 1 and the rear shell 2 develop an accommodating space in between in order to hold a printed circuit board 51 on which there are a conductive spring 521 and a conducting strip 522 as components to deliver electricity into the inner circuits of the remote controller by contacting a negative pole and a positive pole of a battery 4, respectively. Furthermore, the printed circuit board 51 comprises a first control button 511, a second control button 512, a third control button 513 and a fourth control button 514 which are used to control settings related to the printed circuit board 51. The monitor module 6 electrically connected to the printed circuit board 51 is used to display information related to the printed circuit board 51 for control. The front shell 1 is designed to have a first clamping piece 121, a second clamping piece 122, a third clamping piece 123 and a fourth clamping piece 124 at inner edges, which are integrated with the rear shell 2. The rear shell 2 comprises a battery bay 21 with a convex part 211 on the left-hand side whose functions are disclosed hereinafter. The rear shell 2 comprises a first concave part 22 and a second concave part 23 on the right-hand side, a groove 24 on the upper left corner, and a circular groove 26 on the lower right corner (a similar circular groove also designed on the lower left corner of the rear shell 2). The concave parts 22, 23 and the groove 24 are used in assembling the back cover 3; the circular groove 26 is used in assembling the front shell 1. The rear shell 2 further comprises a ringlike part 25 which is penetrated by wires and hung at any object such as a hook. The back cover 3 sinking inward comprises a first clasper 31 and a second clasper 32 which correspond to the first concave part 22 and the second concave part 23 of the rear shell 2 as well as a first clamping part 33, a second clamping part 34, and a third clamping part 35 of the groove 24 on the left, respectively.

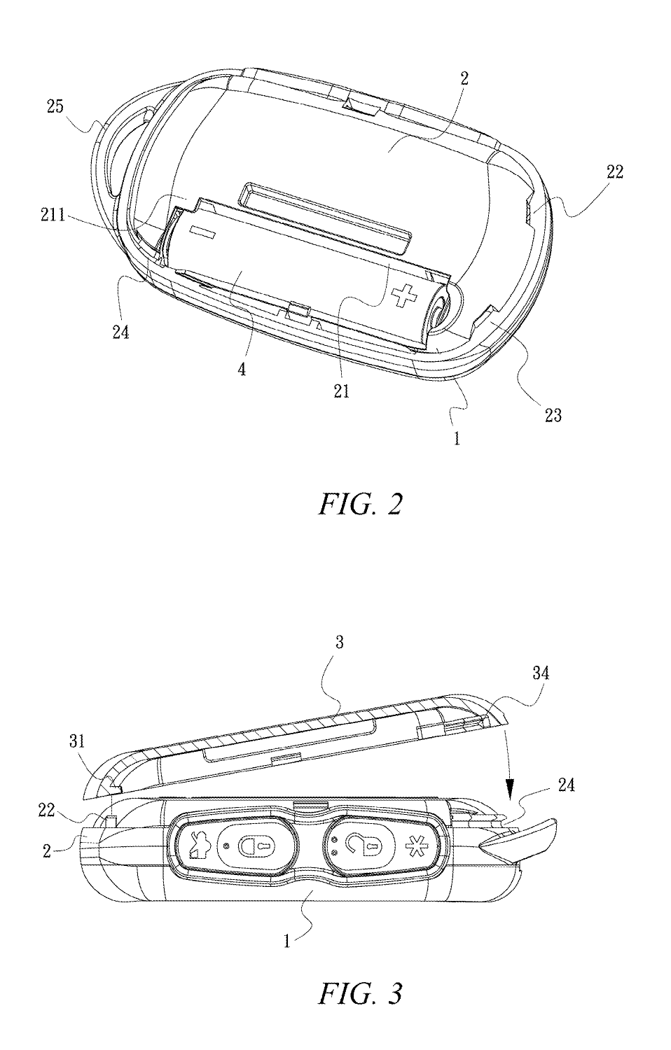

Refer to FIGS. 1 and 2, wherein FIG. 2 is a schematic view of the present invention of a remote controller casing with a front shell and a rear shell assembled. As shown in FIG. 2, the clamping pieces 121, 122, 123 and 124 on the front shell 1 are able to snap circular grooves on the rear shell 2. The first clamping piece 121 and the second clamping piece 122 (the third clamping piece 123 and the fourth clamping piece 124) snap the circular groove 26 (a similar circular groove on the lower left corner of the rear shell 2) in order to completely assemble the front shell 1 and the rear shell 2. The length (width) of the battery bay 21 on the rear shell 2 exactly match a distance between the conductive spring 521 and the conducting strip 522 on one side of the printed circuit board 51 (width designed to install the conductive spring 521 and the conducting strip 522). A battery 4 to be held in the battery bay 21 allows a negative pole to contact the conductive spring 521 which is pressed later for connection of a positive pole with the conducting strip 522; the battery 4 is synchronously fixed by the convex part 211 of the battery bay 21 and protectively and smoothly connected to both the conductive spring 521 and the conducting strip 522 without dropping from the battery bay 21.

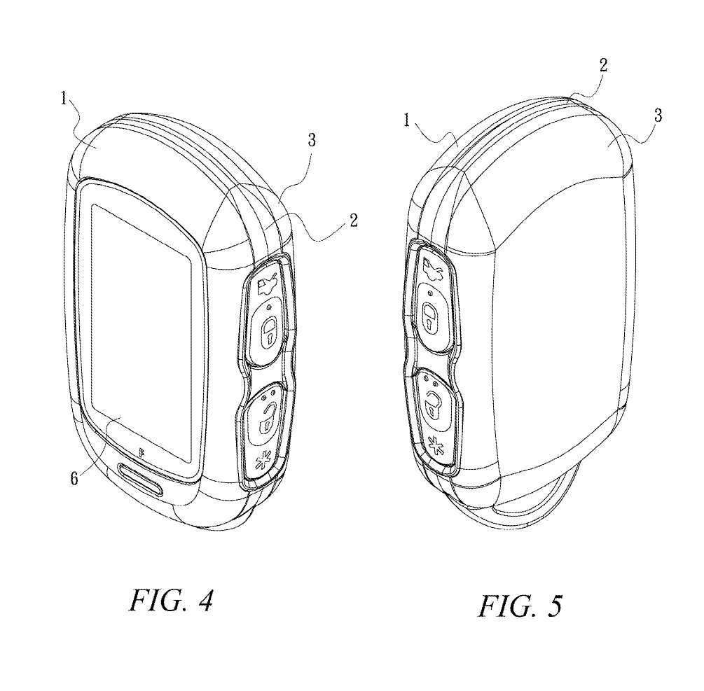

Refer to FIGS. 1 and 3, wherein FIG. 3 is a side view of the present invention of a remote controller casing with a rear shell assembled onto a back cover. As shown in FIGS. 1 and 3, the first clasper 31 and the second clasper 32 at the right interior edge of the back cover 3 are simultaneously inserted into the first concave part 22 and the second concave part 23 of the rear shell 2, respectively; secondly, the rear shell 2 is consequently covered by the back cover 3; finally, the first clamping part 33, the second clamping part 34 and the third clamping part 35 at the left interior edge of the back cover 3 snap the groove 24 on the rear shell 2 under press by a user. FIGS. 4 and 5 illustrate a remote controller casing which has been assembled. FIG. 4 is a front oblique view for the present invention of an assembled remote controller casing with the monitor module 6 installed on the front shell 1; FIG. 5 is a rear oblique view for the present invention of a remote controller casing which has been assembled. It is notable that the present invention is easily assembled (disassembled) with the first clamping part 33, the second clamping part 34 and the third clamping part 35 snapping the groove 24 under press of a finger only (separated from the groove 24 under gentle pull of a finger). As such, the back cover 3 is designed to be replaced simply.

It can be seen from the above disclosures that leverage which is applicable to designs of the concaved parts 22, 23 on the rear shell 2 as well as the claspers 31, 32 on the back cover 3 dominates assembly/disassembly of the present invention and provides significant driving capability. The battery 4 is released from the casing, which is dropped or collided carelessly, in a specific direction near joints of the concaved parts 22, 23 on the rear shell 2 and the claspers 31, 32 on the back cover 3 but not arbitrarily separated from the battery bay 21 under impact because the battery 4 is still held by the back cover 3 which resists resilience of the battery 4 and does not come off with the claspers 31, 32 withstanding and seizing the concaved parts 22, 23. As such, the present invention which is characteristic of not only the back cover 3 designed to be conveniently assembled/disassembled but also the claspers 31, 32 reinforcing an overall structure to prevent the rear shell 2 from dropping under impact of the battery 4 when the remote controller casing is dropped or collided.

The above disclosures are the preferred embodiments of the present invention only and not referred to as examples restricting the present invention; any equivalent modification or change without departing from the spirit or scope of the present invention is still incorporated in claims of the present invention.

What is claimed is:

1. A remote controller casing, comprising:
a front shell;
a rear shell, which has an assembly means with said front shell, wherein said assembly means is coupled and fixed for said rear shell and said frond shell to develop an accommodating space to hold a printed circuit board, and said rear shell further comprises a battery bay whose one interior edge is designed to have a convex part, at least one concave part at one side, and a groove corresponding to said concave part and located at an opposite side; and
a back cover, which comprises at least one clasper at one side which is opposite to said concave part, and at least one clamping part at an opposite side;
wherein, when said front shell is assembled with said rear shell, said battery bay matches a space developed by a conductive spring and a conducting strip which are located at two sides of said printed circuit board respectively, so that a battery is held between said conductive spring and said conducting strip by means of said battery bay and is not separated from said conductive spring and said conducting strip due to said convex part;
wherein, said clasper on said back cover snaps and resists said concave part first, and said rear shell is consequently covered through said clamping part, and then said back cover and said rear shell is combined with said clamping part snapping said groove under press.

2. The remote controller casing of claim 1, wherein said assembly means refers to at least one assembling section which is associated with a relative position between said front shell and said rear shell.

3. The remote controller casing of claim 2, wherein said assembling section comprises components including fastener, screw and threaded hole or a combination of said components used in assembly.

4. The remote controller casing of claim 1, further comprising a monitor module which is electrically connected to said printed circuit board for displaying information related to said printed circuit board.

5. The remote controller casing of claim 1, wherein said printed circuit board further comprises a plurality of push buttons which are able to control settings related to said printed circuit board.

6. The remote controller casing of claim 1, wherein said rear shell further comprises a ringlike part which is used to link or hang said remote controller.
